(19) United States
(12) Patent Application Publication
(10) Pub. No.: US 2009/0183048 A1
(43) Pub. Date: Jul. 16, 2009

(54) Systems and methods for LDPC coded modulation

(75) Inventors: Marcos C. Tzannes, Orinda, CA (US); Arnon Friedmann, Marlboro, MA (US); Todor Cooklev, Salt Lake City, UT (US)

Correspondence Address: Jason H. Vick;Sheridan Ross, PC, Suite # 1200, 1560 Broadway, Denver, CO, 80202, US

(73) Assignee: Aware, Inc., Bedford, MA (US)

(21) Appl. No.: 12/383,056

(22) Filed: Mar. 19, 2009

Related U.S. Application Data
(62) Division of application No. 11/140,246, filed on May 31, 2005.
Application No. 11/140,246 is a division of application No. 09/882,046, filed on Jun. 18, 2001, now abandoned.
(60) Provisional application No. 60/241,468, filed on Oct. 18, 2000.
(60) Provisional application No. 60/212,233, filed on Jun. 16, 2000.

(51) Int. Cl. H03M 13/05; G06F 11/10

(52) U.S. Cl. 714/752; 714/E11.032

(57) ABSTRACT

Typical forward error correction methods employ Trellis Code Modulation. By substituting low density parity check coding in place of the convolution code as part of a combined modulation and encoding procedure, low density parity check coding and modulation can be performed. The low density parity check codes have no error floor, no cycles, an equal bit error rate for the information bits and the parity bits, and timely construction of both a parity check matrix with variable codeword size and a generator matrix is possible.

### RELATED APPLICATION DATA

This application claims the benefit of U.S. Provisional Application Ser. No. 60/212,233 entitled “LDPC Coded Modulation” filed Jun. 16, 2000, and U.S. Provisional Application Ser. No. 60/241,468 entitled “Low Density Parity Check (LDPC) Coded Modulation For ADSL,” filed Oct. 18, 2000, incorporated herein by reference in their entirety.

### BACKGROUND OF THE INVENTION

1. Field of the Invention

This invention relates to communications coding. In particular, this invention relates to a forward error correction coding method for multicarrier environments.

2. Description of Related Art

In conventional communication systems, a combined modulation and coding procedure called Trellis Coded Modulation (TCM) is often used to improve DSL system performance. Ungerbeock first introduced TCM in 1976 and since then it has been used for several telecommunications transmission standards. Particularly, Trellis codes encode a subset of the information bit stream and partition the signal constellations into subsets, i.e., cosets, and then use convolution codes to map information bits to the cosets. Standard ADSL systems use TCM as described in the ITU Standard G.992.1, incorporated herein by reference in its entirety.

Low Density Parity Check (LDPC) codes have also used in conventional communication systems. LDPC codes have been shown to have improved performance when compared to convolution codes. LDPC codes are described, for example, in the paper “Good Error—Correcting Codes Based on Very Sparse Matrices,” by D. J. C. MacKay, IEEE Transactions on Information Theory, 1999, incorporated herein by reference in its entirety. In conventional LDPC coded communication systems, the LDPC code is used as a traditional block code, similar to Reed Solomon Codes or Hamming Codes.

### SUMMARY OF THE INVENTION

However, LDPC codes have not been used in conventional LDPC coded systems as part of a combined modulation and coding procedure, for example, as done in Trellis coded modulation. Accordingly, an exemplary embodiment of the systems and methods of this invention provide a forward error correction coding method for communications based on a low density parity check code. Specifically, an exemplary embodiment of this invention uses an LDPC code in place of a convolution code as part of the combined modulation and coding procedure. This new encoding method will be referred to as LDPC Coded Modulation (LDPCCM).

In an exemplary embodiment of this invention, LDPCCM is used to improve the performance of conventional ADSL systems. Historically, ADSL systems have used TCM. However, in an exemplary embodiment of this invention, LDPCCM replaces the TCM to provide, for example, an improving coding gain. However, in order to use LDPCCM in an ADSL system as described above, the LDPC code should satisfy several exemplary requirements. These requirements can include the code having no error floor and no cycles. Additionally, the code should have an equal bit error rate (BER) for the information bits and the parity bits, and the ability to determine relatively quickly the construction of a parity check matrix with a variable code word size, and a generator matrix.

Designs that satisfy the first requirement of having no error floor and no cycles are known, such as those as described in “LDPC” by D. J. C. MacKay, IEEE Transactions on Communications, 2000, which is incorporated herein by reference in its entirety. The disclosed LDPC code has a code word size of 9979 which does not have any cycles and therefore, does not have an error floor. However, for example, the construction cannot be extended to other code words, e.g., shorter or longer code words cannot be achieved.

Accordingly, and in accordance with an exemplary embodiment of this invention, forward error correction (FEC) coded bit signals are produced by FEC coding a subset of data bit signals using an LDPC code.

Aspects of the invention also relate to using an LDPC code in a multicarrier environment.

Aspects of the invention also relate to providing for improved performance of DSL systems.

Aspects of the invention also relate to providing a coding method for communications over ADSL systems based on low density parity check codes.

Aspects of the invention also relate to providing a low density parity check code used in place of convolution code as a portion of the combined modulation and coding procedure in an ADSL environment.

Aspects of the invention also relate to constructing an LDPC parity check matrix during an initialization or configuration phase.

Aspects of the invention also relate to constructing an LDPC generator matrix during an initialization or configuration phase.

Aspects of the invention also relate to constructing an LDPC parity check matrix after the latency and data rate requirements of a communication system have been determined.

Aspects of the invention also relate to constructing an LDPC generator matrix after the latency and data rate requirements of a communication system have been determined.

These and other features and advantages of this invention are described in, or are apparent from, the following detailed description of the embodiments.

### BRIEF DESCRIPTION OF THE DRAWINGS

The embodiments of the invention will be described in detail, with reference to the following figures wherein:

FIG. 1 is a functional block diagram illustrating an exemplary system for LDPC coded modulation;

FIG. 2 illustrates an exemplary graphical representation of a parity check matrix;

FIG. 3 illustrates an exemplary random parity check code;

FIG. 4 illustrates an exemplary structure of a parity check matrix;

FIG. 5 is a flow chart outlining an exemplary embodiment for determining LDPC codes;

FIG. 6 is a flow chart illustrating a second exemplary embodiment for determining LDPC codes; and

FIG. 7 is a flow chart illustrating an exemplary method of determining a random number.

### DETAILED DESCRIPTION OF THE INVENTION

In relation to the first requirement of the LDPC code having no error floor and no cycles, an ADSL system must operate at very low bit error rates (BER) because they often carry information that is highly sensitive to bit errors, such as video information. For this reason, ADSL systems are often specified to operate at a BER of less than 1E-7. As a result, LDPCCM should not have an error floor. An error floor of a forward error correcting (FEC) code is defined as a non-zero BER at a very high signal-to-noise ratio (SNR). Many codes do not have an error floor. For example, as a signal-to-noise ratio SNR of a channel increases (approaches infinity) the BER continues to decrease (approach zero). Turbo codes are an example of a coding method that does exhibit an error floor. This means that at a very high SNR, the BER for turbo codes will remain constant. Therefore, according to an aspect of this invention, an LDPC code is constructed to not have an error floor by insuring that there are no cycles in the code.

In relation to the second requirement of the code having an equal bit error rate (BER) for the information bits and the parity bits, in conventional LDPC coded systems, LDPC codes are used as simple block codes. In these systems, the parity bits are sent as part of the codeword along with the information bits over the channel. At the receiver, the parity bits are used for decoding an error correction of the information bits. After the decoding process is complete, the parity bits are discarded. As a result, the actual BER of the parity bits is not important. For this reason, conventional LDPC coded systems often use codes that have a different BER on the parity bits and the information bits.

According to an exemplary embodiment of this invention, the encoded bits, i.e., the information and parity bits, are used to designate the constellation coset. Therefore, it is important that all of the encoded bits have an equal BER because both the parity and the information bits are used to determine which coset is to be used for decoding. In particular, the LDPC codes are constructed with equal BER on the information bits and the parity bits at least by insuring the LDPC parity check matrix has the same number of branches connecting the information bits and the parity bits with the parity nodes, and the parity nodes are connected to an equal number of information bits and parity bits.

ADSL systems are variable rate and variable latency systems. This means that an ADSL transceiver can be configured to operate at many different data rates. As an example, ITU Standard G.992.1 requires that the ADSL transceiver be capable of operating at rates from 64 kbps to 6 Mbps in increments of 32 kbps. ADSL systems are also variable latency systems. This means that an ADSL transceiver must be capable of operating at many different latency, i.e., delay, levels. As an example, ITU standard G.992.1 requires that the ADSL transceiver be capable of operating at latency levels of, for example, 1.5 msecs to 20 msecs.

The variable rate and variable latency requirements of ADSL systems place difficult design constraints on the type of FEC coding that can be used, because, for example, for any particular data rate, the system must also support many different latency levels. For example, when the data rate is low, e.g., 64 kbps and the latency requirement is low, e.g., 1.5 msecs, a very low latency FEC code must be used.

The low latency FEC block codes are designed by using short codeword lengths. In general, the longer the codeword, the higher the coding gain of the FEC code. However, in addition, a longer codeword results in increased latency. It follows that a well designed FEC code for ADSL systems must be capable of adapting the codeword length based on the latency and the data rate requirements. In this manner, the FEC code will provide the maximum possible coding gain based on the latency and data rate requirements.

Therefore, according to an exemplary embodiment of this invention, an LDPC code is constructed that can have a variable codeword length. This variable codeword length LDPC code, i.e., parity check matrix, is determined after the data rate and the latency requirements are specified. In this way, for example, a single transceiver can be configured for a large array of data rates and latency levels without having to store a large number of LDPC codes with different codeword lengths. Thus, once the latency and data rate requirements are specified, the construction of the LDPC code determines a codeword length that maximizes the coding gain while meeting the data rate and the latency requirements. As an example, ADSL transceivers are variable data rate and variable latency systems. This means that they can be configured to operate with different data rates and latency depending on for example the level of service (as provided by service provider), the application, the telephone line quality, or the like. For example, when a consumer buys ADSL service from an ADSL service provider, the consumer will buy a level of service that is specified by the data rate capability. For example, a consumer could buy an ADSL service that guaranteed a 384-1536 kbps data rate from the central office into the consumers residence. Depending on the condition of the phone line and the distance from the central office, the consumer would get a data rate somewhere in the range of 384-1536 kbps. In addition the consumer would be guaranteed a certain latency based on the level of service, for example, 5 msecs. Therefore after the ADSL transceivers were installed the data rate would be determined based on the factors mentioned above. Based on this data rate and the service latency requirement an LDPC code would be constructed that would maximize the coding gain, i.e., codeword size for this data rate and latency. In particular, an ADSL transceiver would first measure, for example during a an initialization or training phase, the data rate capability of the phone line and then based on the data rate allowed by the ADSL service the ADSL transceiver would determine the operational data rate. After the operational data rate is determined and based on the service latency requirement the ADSL transceiver would construct the LDPC code.

Alternatively the latency and/or data rate requirements could also be set based on the expected application that will run over the ADSL connection, such as video, and in this case the LDPC code would be constructed after the application requirements have contributed in determining the data rate and latency.

To facilitate the timely construction of the parity check matrix, it should be performed simply so that the construction can be completed during, for example, the initialization or configuration phases of a transceiver. For example, in ADSL transceivers measure the Signal to Noise Ratio (SNR) of the channel, i.e., a telephone line, during initialization and establish the operational data rate based on this SNR. Additionally, as stated above, the ADSL service level and application may factor in the determination of the data rate. The latency is also determined during either the initialization phase or during configuration of the transceivers, i.e., when the ADSL service is first installed. After the data rate and latency have been specified the LDPC code is constructed.

Relating to the construction of the generator matrix, the generator matrix of an LDPC code is used to create the LDPC codewords at the LDPC encoder. The generator matrix is typically derived from the parity check by performing Gaussian elimination on the parity check matrix. As discussed above in relation to the determination of the parity check matrix with a variable codeword size, in ADSL systems the LDPC code must be timely generated in order to have a variable codeword size. Thus, the generator matrix is also generated in a timely manner, such as on-the-fly, or after the data rate and latency requirements are specified.

A parity check matrix of a code is a matrix that when multiplied by any codeword results in an all-zero vector. Mathematically, this can be written as:

Let H be the parity check matrix of the code, and c be any codeword in the code C, then:

cH^{T}=Õ

A generator matrix of a code is a matrix that when multiplied by an input vector results in a codeword. Mathematically, this is represented as:

Let G be the parity check matrix of the code, and a be any data vector, then:

aG=cεC

where C is a set of all codewords. For example, given a parity check matrix:

H =

| | | | | | | |
|---|---|---|---|---|---|---|
| 1 | 0 | 0 | 1 | 0 | 1 | 1 |
| 0 | 1 | 0 | 1 | 0 | 1 | 0 |
| 0 | 0 | 1 | 0 | 1 | 1 | 1 |

and a generator matrix:

G =

| | | | | | | |
|---|---|---|---|---|---|---|
| 1 | 1 | 0 | 1 | 0 | 0 | 0 |
| 0 | 1 | 1 | 0 | 1 | 0 | 0 |
| 1 | 1 | 1 | 0 | 0 | 1 | 0 |
| 1 | 0 | 1 | 0 | 0 | 0 | 1 |

Then, for the input vector a={0,1,0,0}, the resulting codeword is:

c=aG={0,1,1,0,1,0,0}.

This also yields:

cH^{T}={0,0,0},

as required.

Notice, that in this example, both the parity check matrix and the generator matrix are systematic, i.e., the identity matrix is present in some portion of the matrices:

−H=[I;H′} and G=[G′;I].

Notice that in this case, H′=G′^{T}.

The parity check matrix for an LDPC code is generated by randomly assigning ones to the rows in the parity check matrix (H in the above example). The number of columns is equal to the number of information bits K, plus the number of parity bits (P). The number of rows is equal to the number of parity bits.

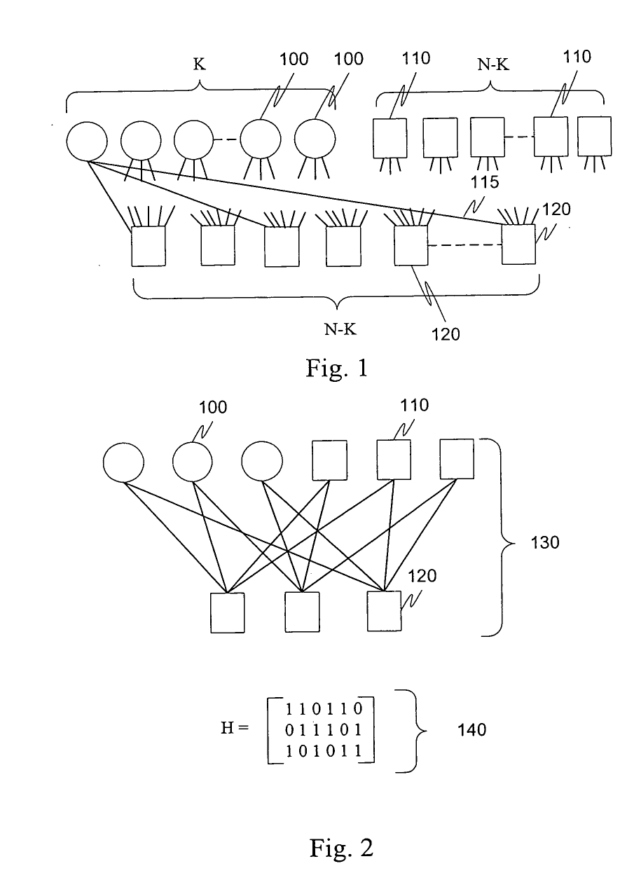

FIG. 1 illustrates an exemplary parity check matrix where the circles represent the information bits 100 and the squares represent the parity bits 110. The lines 115 connecting the information bits and the parity bits represent the ones in the parity check matrix, and also represent the parity check equation which must be satisfied by a codeword. Looking at the bottom row of squares 120, the sum (modulo 2) of all the bits that are connecting to a square along the bottom row must equate to zero for a codeword.

FIG. 2 illustrates an exemplary random parity check code 130. In this example, there are three information bits 100 and three parity bits 110. There are two connections 115 from each bit along the top row to the check node 120 along the bottom row. Since there are only three check nodes 120, each check node has four connections to the information and the parity bits. The parity check matrix H 140 for the parity check code 130 is also shown. Notice that each column of the parity check matrix 140 has two ones, and each row has four ones. This is analogous to the graphical representation of the parity check code 130.

Both FIGS. 1 and 2 represent regular parity check matrices which imply that there are an equal number of ones in each column, and an equal number of ones in each row of the parity check matrix. FIG. 2 also illustrates a case where each parity check node 120 connects to an equal number of the information and the parity bits.

This last point about finding a generator matrix is important when considering the construction of the LDPC codes. Specifically, in order to obtain a generator matrix for the code described by a general parity check matrix, Gaussian elimination is performed on the parity check matrix to form a systematic parity check matrix and then the generator matrix is obtained by taking the transpose of the matrix H. However, a randomly constructed H matrix may not be “full rank” and therefore may not be possible to form a length N code from the parity check matrix. In actuality, the codeword length is often slightly less than N, usually within three bits.

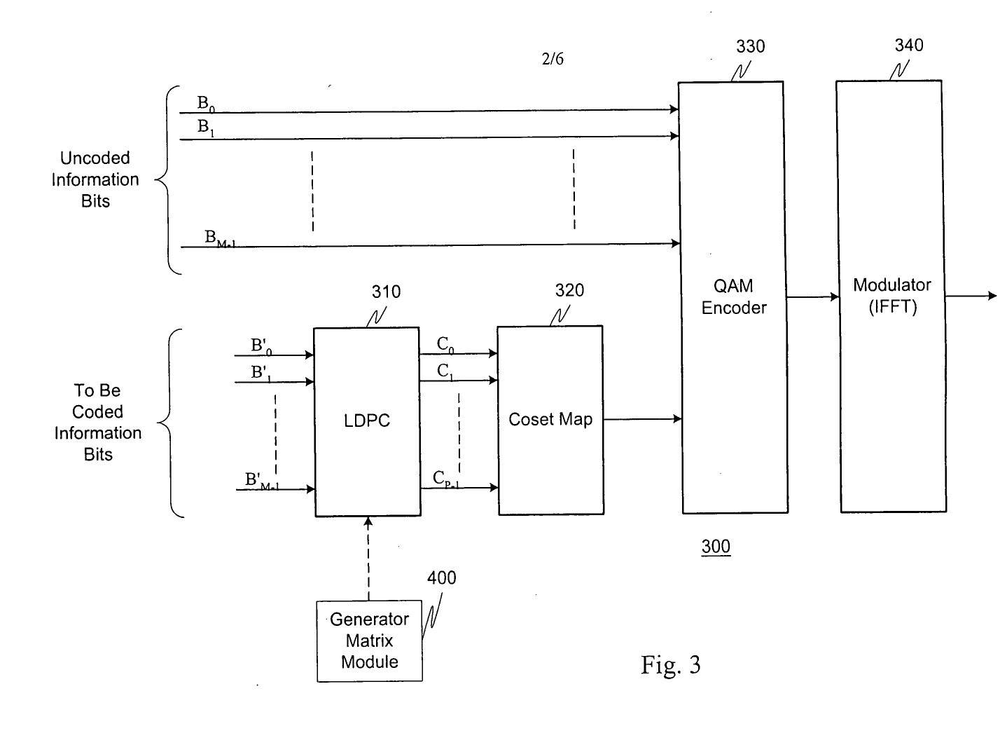

FIG. 3 illustrates an exemplary LDPC coder according to this invention. The remainder of the hardware and software necessary for ADSL communication will not be described herein since ADSL transceiver configurations are well known and can be found, for example, in the ITU Standard G.992.1. The LDPC coder 300 comprises a LDPC encoder module 310, a coset map determination module 320, a QAM encoder 330, and a modulator 340. Inputs paths B_{M} represent incoming uncoded information bits. Input information streams B′_{M} represent incoming to be coded information bits. The information in streams C_{N} represent LDPC coded bits. Also associated with the LDPC coder 300 is a generator matrix module 400.

The code rate can be expressed as:

$$CodeRate = \frac{M}{P}$$

The LDPCCM receiver contains the inverse functions of FIG. 3, with the LDPC decoding being performed using the LDPC parity check matrix. The parity check matrix is constructed using a parity check construction module which resides in the receiver.

As stated above, the LDPC parity check matrix is constructed after the data date and latency parameters have been specified during an initialization or configuration phase. The construction of the LDPC parity check matrix is performed at the receiver and commences with the rate and branch determination module (not shown) selecting the code rate and the number of branches from each information and each parity bit to each parity node. The number of these branches is represented by (t). The branches are randomly assigned, based on a random number determined in a random number module (not shown), such as a pseudo-random shift register (PRBS), from each bit to a parity node based on t number of cycles through the information and the parity bits. This insures that t branches exist from each of the information and the parity bits. If a branch is assigned from the same bit to the same parity node as in earlier iteration, a new random number is selected and a new branch chosen.

Two options are available to ensure all nodes are fully populated. Specifically, the system can determine an equal number of branches from all parity nodes, or, alternatively, equal connections from all the parity nodes to both the parity bits and the information bits. For an equal number of branches in all parity nodes, a counter (not shown) is assigned to each parity node and incremented every time a branch is connected to that node. Once the counter reaches 2t, no more connections are allowed to be made to that node. If a randomly generated branch chooses a “full” node, the random number is discarded and new branch chosen. An efficient method for this is to choose random numbers in the range 1-(N-k-f) where f is a number of “full” nodes. However, if towards the end of the branch population it becomes difficult to avoid duplicate branches, the process can be restarted or a few bits can be chosen to have less than t branches.

For equal connections from the parity nodes to both the parity bits and the information bits, two counters are assigned to each parity node to count the parity bit and the information bit branches separately. The branches are then chosen such that no node is allowed to exceed its allocated number of connections to either the information or the parity bits. This can be achieved in the same manner as discussed above in relation to the embodiment where equal branches are present in all parity nodes. However, in this exemplary scenario, instead of having “full” nodes, there exist “full information” nodes and “full parity” nodes.

Next, the cycles, which can be of any length, can be eliminated by searching through the parity check matrix and reassigning the branches that form the cycles with the other branches so that the cycles are removed. Reassigning the branches in a manner consistent with the looping step discussed above, however, may be computationally complex so it is possible to simply remove the branches from the cycles and allowing some of the nodes and the bits to have an unequal number of connections without impacting the performance of the system.

At the transmitter, the generator matrix is determined by the generator matrix module 400 after the data rate and latency parameters have been specified during an initialization or configuration phase. Specifically, using Gaussian elimination, a systematic parity check matrix is created. From the systematic matrix, the generator matrix is created as discussed above. If the parity check matrix is not full rank, which implies that the codeword length would be less than desired, there are two options. First, the looping as discussed above can be re-executed. Alternatively, more information bits than needed for the desired code rate can be selected and the remaining steps subsequently performed. However, this may lead to unequal branches for the parity nodes.

If the matrix is not full rank, one or more rows can be eliminated as necessary. If the resulting code has extra information bits, these extra bits can be assumed to be zero for the purposes of encoding and decoding, while never needing to be transmitted.

Alternatively, a second exemplary method for generating LDPC codes is faster than the above-described method, at the cost of the number of features of the overall code structure. The main difference with this exemplary method of generating LDPC codes is that the parity check matrix will be constrained so that the columns forming the parity bit section of the matrix will be lower triangular in structure. Since it is known that if the lower triangular section is the identity matrix, then the generator matrix is relatively uncomplicated to determine. As it turns out, it is sufficient that the parity bit section be lower triangular in nature.

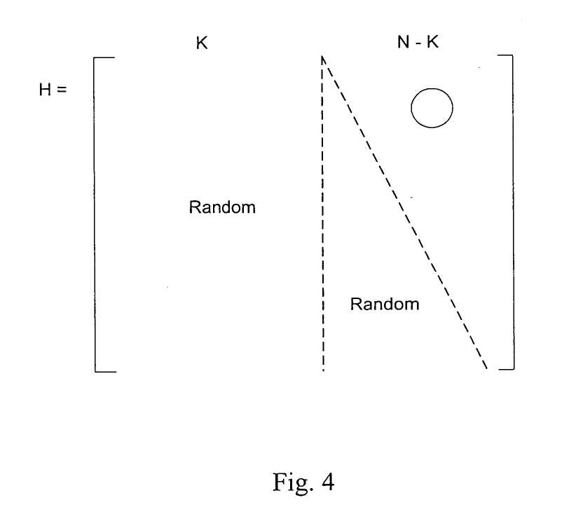

FIG. 4 illustrates the structure of an exemplary parity check matrix for this construction. Lower triangular applies to a square matrix where any and all non-zero terms are on or below the main diagonal from 1,1 to N,N, i.e., everything above the main diagonal is zero. In this exemplary case, the section of the parity check matrix which is for the parity bits, the last N-K columns form a square matrix of size N-K×N-K. This is the section that needs to be lower triangular. The section for the information bits is not constrained. Thus, the section referred to as being the identity matrix (for the trivial case) is the parity bit section which would make an N-K×N-K identity matrix. Therefore, the identity matrix (or any diagonal matrix) is a subset of the lower triangular matrices.

An advantage to this construction, combined with the random number generation described below, is that neither the parity check matrix, nor the generator matrix need be stored. The branches needed any point in time during either the encoding or decoding can be determined from the PRBS as needed. This proves advantageous as the codeword size increases and the matrix size increases. Additionally, the normal method of creating LDPC codes via Gaussian elimination results in a generator matrix that is non-sparse and requires a large amount of storage for the encoder.

One way of using this method to the advantage of the encoder is to set all parity nodes equal to zero. As the information bits arrive, the parity node connections are determined with, for example the PRBS, and the information bits are XORed with the parity nodes. Next, the first parity bit is set equal to the value of the first parity node, and this value is XORed with the other parity nodes that are connected to the first parity bit. These connections are again determined by, for example, the PRBS.

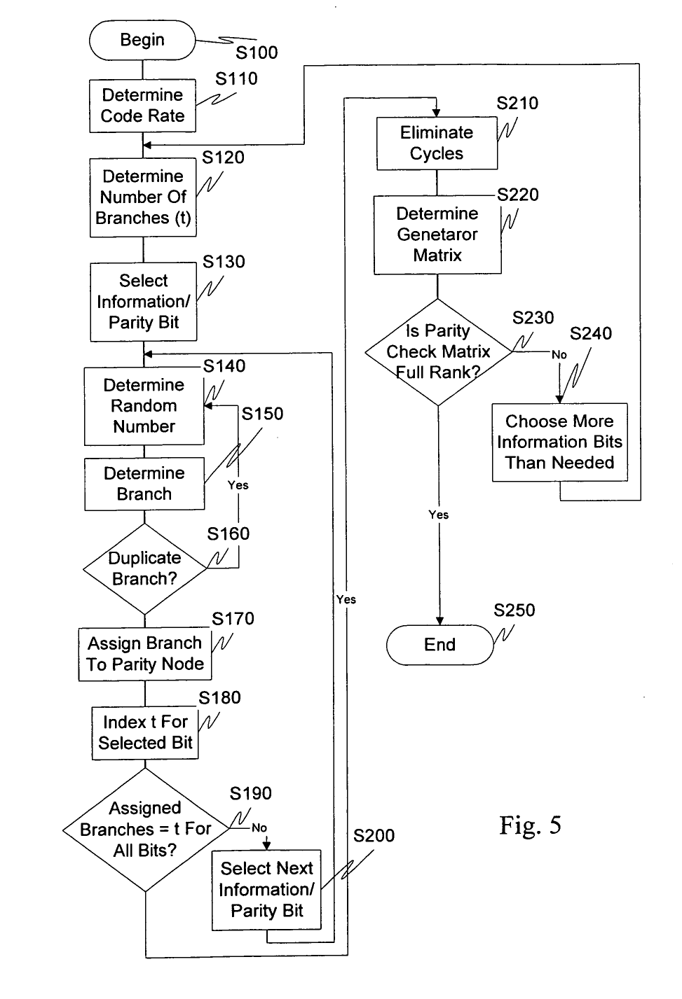

FIG. 5 illustrates a first exemplary method of determining LDPC codes according to this invention. In particular, control begins in step S100 and continues to step S110. In step S110, the code rate is determined. Next, in step S120, the number of branches (t) is determined. Control then continues to step S130.

In step S130, an information or parity bit is selected. Next, in step S140, a random number is determined. Then, in step S150, a branch from the selected information or parity bit is determined. Control then continues to step S160.

In step S160, a determination is made whether the determined branch is a duplicate. If the branch is a duplicate, control jumps back to step S140. Otherwise, control continues to step S170.

In step S170, the branch is assigned to the parity node. Next, in step S180, t is indexed for the selected bit. Then, in step S190, a determination is made whether the assigned number of branches is equal to t for all information and parity bits. If the information and the parity bits do not have t branches assigned, control continues to step S200. Otherwise, control jumps to step S210.

In step S200, the next information or parity bit is selected. Control then continues back to step S140.

In step S210, the cycles are eliminated. Next, in step S220, the generator matrix is determined. Then, in step S230, a determination is made whether the parity check matrix is full rank. If the parity check matrix is not full rank, control continues to step S240. Otherwise, control jumps to step S250 where the control sequence ends.

In step S240, more information bits than are needed are chosen and control jumps back to step S120.

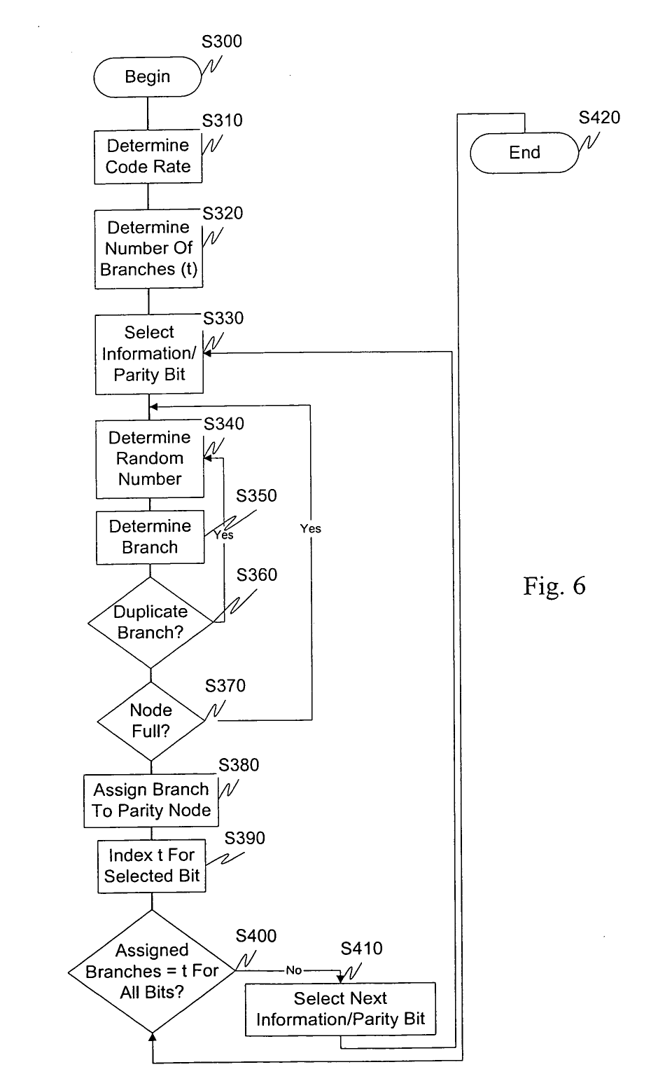

FIG. 6 illustrates a second exemplary embodiment of determining LDPC codes according to this invention. In particular, control begins in step S300 and continues to step S310. In step S310, the code rate is determined. Next, in step S320, the number of branches (t) is determined. Then, in step S330, an information and/or parity bit is selected. Control then continues to step S340.

In step S340, a random number is determined. Next, in step S350, a branch between the selected information or parity bit and parity node is determined. Then, in step S360, a determination is made whether the branch is a duplicate. If the branch is a duplicate, control jumps back to step S340. Otherwise, control continues to step S370. In step S370, a determination is made whether the parity node is full. If the parity node is full, control jumps back to step S340. Otherwise, control continues to step S380.

In step S380, the branch is assigned to the parity node. Next, in step S390, t is indexed for the selected information or parity bit. Then, in step S400, a determination is made whether t branches are assigned to all information and parity bits. If t branches are not assigned to all information and parity bits, control continues to step S410. Otherwise, control jumps to step S420 where the control sequence ends.

In step S400, the next information or parity bit is selected. Control then continues back to step S330.

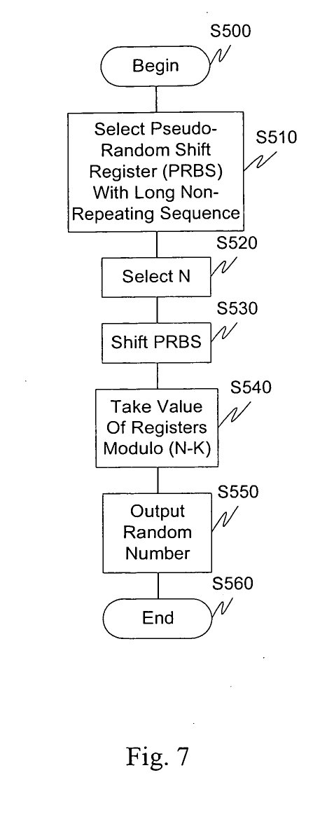

FIG. 7 illustrates an exemplary method of determining a random number as indicated in steps S140 and S340. In particular, control begins in step S500 and continues to step S510. In step S510, a random number, for example from a pseudo-random shift register (PRBS) with long non-repeating sequence, is selected. Next, in step S520, N is selected. Then, in step S530, the PRBS is shifted. Control then continues to step S540.

In step S540, the value of the registers modulo (N-K) is taken. Next, in step S550, the random number is output. Control then continues to step S560 where the control sequence ends.

As illustrated in FIG. 3, the LDPC code determination system and related components can be implemented either on a DSL modem, such as a VDSL modem, or separate programmed general purpose computer having a communication device. However, the LDPC code determination system can also be implemented in a special purpose computer, a programmed microprocessor or a microcontroller and peripheral integrated circuit element, an ASIC or other integrated circuit, a digital signal processor, a hardwired or electronic logic circuit such as a discrete element circuit, a programmable logic device, such as a PLD, PLA, FPGA, PAL, or the like, and associated communications equipment. In general, any device capable of implementing a finite state machine that is in turn capable of implementing the flowcharts illustrated in FIGS. 5-7 can be used to implement the LDPC code determination system according to this invention. Additionally, the term module as used herein can encompass any hardware or software, or combination thereof.

The LDPCCM method may be used in any wireless, wireline or in general any communication system to provide improved coding over conventional communication systems. The LDPCCM method may be used in any communication system that uses multicarrier or single carrier modulation. Furthermore, this LDPCCM method may be used in any communication system with variable data rate and latency requirements where these data rate and latency requirements are determined for example during an initialization or configuration phase.

Furthermore, the disclosed method may be readily implemented in software using object or object-oriented software development environments that provide portable source code that can be used on a variety of computers, work stations, or modem hardware and/or software platforms. Alternatively, disclosed modem may be implemented partially or fully in hardware using standard logic circuits or a VLSI design. Other software or hardware can be used to implement the systems in accordance with this invention depending on the speed and/or efficiency requirements of this system, the particular function, and the particular software and/or hardware systems or microprocessor or microcomputer systems being utilized. The LDPC code determination system illustrated herein, however, can be readily implemented in a hardware and/or software using any known later developed systems or structures, devices and/or software by those of ordinary skill in the applicable art from the functional description provided herein and with a general basic knowledge of the computer and telecommunications arts.

Moreover, the disclosed methods can be readily implemented as software executed on a programmed general purpose computer, a special purpose computer, a microprocessor and associated communications equipment, a modem, such as a DSL modem, or the like. In these instances, the methods and systems of this invention can be implemented as a program embedded on a modem, such as a DSL modem, or the like. The LDPC code determination system can also be implemented by physically incorporating the system and method into a software and/or hardware system, such as a hardware and software system of a modem, such as an ADSL modem, VDSL modem, network interface card, or the like.

It is, therefore, apparent that there has been provided in accordance with the present invention, systems and methods for determining a LDPC code. While this invention has been described in conjunction with a number of embodiments, it is evident that many alternatives, modifications and variations would be or are apparent to those of ordinary skill in the applicable art. Accordingly, applicants intend to embrace all such alternatives, modifications, equivalents and variations that are within the spirit and the scope of this invention.

1-12. (canceled)

13. A method of forward error correction coding of data bit signals using LDPC codes comprising:
determining at least one of a data rate and a latency; and
determining a LDPC generator matrix that encodes data bit signals.

14. The method of claim 13, wherein the at least one of a data rate and a latency are determined during an initialization or a configuration phase.

15. The method of claim 13, wherein the LDPC generator matrix is determined after the data rate and the latency have been determined.

16. The method of claim 13, wherein the LDPC code has a variable codeword length.

17. The method of claim 16, wherein the codeword length is varied depending on one or more of the data rate and the latency.

18. The method of claim 13, wherein the LDPC code does not have any cycles.

19-24. (canceled)

25. An information storage media comprising information that performs forward error correction coding of data bit signals using LDPC codes comprising:
information that determines at least one of a data rate and a latency; and
information that determines a LDPC generator matrix that encodes data bit signals.

26. The media of claim 25, wherein the at least one of a data rate and a latency are determined during an initialization or a configuration phase.

27. The media of claim 25, wherein the LDPC generator matrix is determined after the data rate and the latency have been determined.

28. The media of claim 25, wherein the LDPC code has a variable codeword length.

29. The media of claim 28, wherein the codeword length is varied depending on one or more of the data rate and the latency.

30. The media of claim 25, wherein the LDPC code does not have any cycles.

31-36. (canceled)
